(19) United States
(12) Patent Application Publication
(10) Pub. No.: US 2015/0206938 A1
(43) Pub. Date: Jul. 23, 2015

(54) METHOD FOR MANUFACTURING A MULTILAYER STRUCTURE ON A SUBSTRATE

(71) Applicant: Commissariat à I'énergie atomique et aux energies alternatives, Paris (FR)

(72) Inventors: Umberto Rossini, Coublevie (FR); François Templier, Grenoble (FR)

(21) Appl. No.: 14/369,698

(22) PCT Filed: Dec. 29, 2012
(86) PCT No.: PCT/FR2012/053091

§ 371 Date: Jun. 29, 2014

(30) Foreign Application Priority Data
Dec. 29, 2011 (FR) 11/62523

(51) Int. Cl. H01L 29/16; B32B 17/06; H01L 21/762; H01L 29/04; H01L 23/00

(52) U.S. Cl. CPC H01L 29/16; H01L 29/04; H01L 29/045; H01L 24/83; H01L 21/76251; B32B 17/06; H01L 2224/83896; B32B 2457/14

(57) ABSTRACT

The invention relates to a method for manufacturing a multilayer structure on a first substrate made of a first material having a Young's modulus Ev, the method including: using a second substrate having a planar surface covered by the multilayer structure, the second substrate being made of a second material having a Young's modulus Es that is different from the Young's modulus Ev, and a thickness es, the mean Young's modulus Es over thickness es, measured in any direction in a plane parallel to said surface, being constant, plus or minus 10%; bonding the first substrate to the multilayer structure; and removing the second substrate.

### CROSS-REFERENCE TO RELATED APPLICATIONS

The present application is a National Stage of PCT International Application Serial Number PCT/FR2012/053091, filed Dec. 27, 2012, which claims priority under 35 U.S.C. §119 of French Patent Application Serial Number 11/62523, filed Dec. 29, 2011, the disclosures of which are incorporated by reference herein.

### BACKGROUND OF THE INVENTION

1. Field of the Invention

The present invention relates to a method of manufacturing a multilayer structure, for example corresponding to an integrated circuit wafer, on a final support by molecular bonding. The present invention also relates to an initial support for such a multilayer structure.

2. Description of the Related Art

For certain applications, it is desirable to form an integrated circuit wafer on a support. In particular, for applications in optics, the support should be isolating and transparent. It for example is glass. An example of application relates to the manufacturing of a transmissive display screen.

FIGS. 1A to 1C show simplified cross-section views of structures obtained at successive steps of a method of manufacturing an integrated circuit wafer on a support by molecular bonding.

FIG. 1A schematically shows an element 10 having an SOI (Silicon On Insulator) structure.

Element 10 comprises an initial support 12, for example, a single-crystal silicon substrate. Thickness e1 of initial support 12 is for example a few hundred micrometers and is, for example, equal to approximately 700 μm. Initial support 12 may correspond to a cylinder having a diameter greater than some hundred millimeters, and is equal, for example, to approximately 200 mm or 300 mm. Initial support 12 comprises a planar surface 13 covered with an insulating layer 14, for example, made of silicon dioxide. Thickness e2 of insulating layer 14 is for example in the order of 1 μm. Insulating layer 14 is covered with an integrated circuit wafer 16. Integrated circuit wafer 16 comprises a stack of layers having active and/or passive electronic components and conductive tracks connecting these components. As an example, integrated circuit wafer 16 comprises a layer 18 of a semiconductor material, for example, single-crystal silicon, covering insulating layer 14 and having the active and/or passive electronic components, for example, transistors 20, formed inside and on top of it. Integrated circuit wafer 16 further comprises a stack of insulating layers 22, for example, made of silicon dioxide, covering silicon layer 18 and having tracks 24 and vias 26 of a conductive material, capable of coming into contact with the electronic components, formed therein. As an example, thickness e3 of wafer 16 is in the order of a few micrometers. The last insulating layer of stack 22 of insulating layers forms a planar upper surface 28 opposite to support 12.

FIG. 1B shows the structure obtained after the performing of a molecular bonding between surface 28 of element 10 and a final support 30. Final support 30 is made of a material different from silicon, for example, made of glass. Thickness ev of final support 30 is greater than several hundred micrometers, and is, for example, equal to approximately 700 μm. Final support 30 comprises a surface 32 applied against surface 28. Molecular bonding comprises creating a bond between surfaces 28 and 32 without adding any external material (such as glue or an adhesive material). To achieve this, surfaces 28 and 32, properly cleaned, are placed in contact with each other at ambient temperature. A pressure may be locally exerted on support 30 to initiate the bonding. The propagating front of the bonded area then spreads from the initiation region over all of the opposite surfaces.

FIG. 1C shows the structure obtained after the removal of initial support 12. The removal of initial support 12 may comprise a step of chem.-mech. rectification to remove most of initial support 12 followed by a step of selective chemical etching to remove the rest of initial support 12. Insulating layer 14 may be used as a stop layer on removal of initial support 12.

The method then generally carries on with the forming of conductive vias through insulating layer 14 and silicon layer 18 and connected to metal tracks 24 of integrated circuit wafer 16. The forming of these vias comprises photolithography steps, including steps where a resist layer covering insulating layer 14 is exposed to a radiation through a mask to reproduce the mask pattern on the resin layer. To achieve this, the exposure device, which particularly comprises the optical systems for forming the pattern in the resist layer, should be accurately placed with respect to integrated circuit wafer 16.

In an industrial scale manufacturing process, the photolithography steps should be carried out as fast as possible. To achieve this, the exposure device is previously adjusted so that the pattern to be transferred forms properly with no additional adjustment in the resin layer for an integrated circuit wafer which would have the expected dimensions.

However, deformations can be observed in integrated circuit wafer 16 after the bonding step. In particular, a narrowing is observed, that is, two marks formed on bonding surface 28 before the bonding step have come closer to each other after the bonding step.

Further, the relative deformations observed in integrated circuit wafer 16 in a plane parallel to surface 28 generally vary according to the considered direction. Thereby, the observed relative narrowing may vary between approximately 16 ppm and 24 ppm along the considered direction, parallel to surface 28.

An average deformation of 20 ppm can generally be compensated for by the exposure device. However, it is not possible to correct, with the exposure device, relative deformation differences which vary along the considered direction. Thereby, there may be misalignments between the exposure device and the integrated circuit wafer during the photolithography steps carried out after the bonding.

A method of manufacturing by molecular bonding a multilayer structure, for example, corresponding to an integrated circuit wafer, on a final support where deformation differences in the integrated circuit wafer which result from the bonding operation are decreased, or even suppressed, is thus needed.

### SUMMARY OF THE INVENTION

An object of the present invention is to provide a method of manufacturing a multilayer structure on a support by molecular bonding which overcomes the disadvantages of known methods.

According to another object of the present invention, differences in relative deformations along the considered direction in the integrated circuit wafer which result from the bonding operation are substantially suppressed.

According to another object of the present invention, the molecular bonding manufacturing method comprises a decreased number of additional steps with respect to a known molecular bonding manufacturing method.

Thus, the present invention provides a method of manufacturing a multilayer structure on a first support made of a first material having a Young's modulus Ev. The method comprises using a second support having a planar surface covered with the multilayer structure, the second support being made of a second material having a Young's modulus Es, different from Young's modulus Ev, and a thickness es, the average of Young's modulus Es across thickness es, measured along any direction in a plane parallel to said surface, being constant to within 10%. The method further comprises bonding the first support to the multilayer structure and removing the second support.

According to an embodiment of the invention, the second material is a single-crystal material.

According to an embodiment of the invention, Young's modulus Es is anisotropic.

According to an embodiment of the invention, the second support comprises a stack of a third support having a first planar surface and of a fourth support having a second planar surface in contact with the first surface, the first and second surfaces being parallel to said surface. The first and second surfaces are crystallographic surfaces of type (001) and the [100] crystallographic direction of the first surface is inclined by 45° with respect to the [100] crystallographic direction of the second surface.

According to an embodiment of the invention, the first support has a thickness ev and thickness es verifies, to within 10%, relation:

$${e}_{s} = \frac{{E}_{v}}{{E}_{s}} {e}_{v} .$$

According to an embodiment of the invention, the second support initially has a thickness greater than thickness es, the method further comprising thinning the second support down to thickness es.

According to an embodiment of the invention, the second material is single-crystal silicon.

According to an embodiment of the invention, the surface is a [111] crystallographic surface.

According to an embodiment of the invention, the first material is glass.

The present invention also provides a support for a multilayer structure, the multilayer structure being intended to be bonded to an additional support made of a first material having a Young's modulus Ev, the support having a planar surface covered with the multilayer structure, the support being made of a second material having a Young's modulus Es, different from Young's modulus Ev, and a thickness es, the average of Young's modulus Es across thickness es, measured along any direction in a plane parallel to said surface, being constant to within 10%.

According to an embodiment of the invention, the support comprises a stack of a third support having a first planar surface and of a fourth support having a second planar surface in contact with the first surface, the first and second surfaces being parallel to said surface. The first and second surfaces are crystallographic surfaces of type (001). The crystallographic direction of the first surface is inclined by 45° with respect to the crystallographic direction of the second surface.

According to an embodiment of the invention, the second material is single-crystal silicon, said surface being a [111] crystallographic surface.

According to an embodiment of the invention, the additional support has a thickness ev, and thickness es verifies, to within 10%, relation:

$${e}_{s} = \frac{{E}_{v}}{{E}_{s}} {e}_{v} .$$

### BRIEF DESCRIPTION OF THE DRAWINGS

The foregoing and other features and advantages will be discussed in detail in the following non-limiting description of specific embodiments in connection with the accompanying drawings, among which:

FIGS. 1A to 1C, previously described, show the structures obtained at successive steps of a known method of manufacturing an integrated circuit wafer on an insulating support; and

FIG. 2 shows the variation of the Young's modulus in a (100) plane of a single-crystal silicon support;

FIGS. 3A to 3E show the structures obtained at successive steps of an embodiment of a method of manufacturing an integrated circuit wafer on an insulating support according to the present invention;

FIG. 4 shows the variation of the Young's modulus in a plane parallel to the bonding surface of a silicon support according to the invention; and

FIGS. 5A to 5F show the structures obtained at successive steps of an embodiment of a method of manufacturing an integrated circuit wafer on an insulating support according to the present invention.

### DESCRIPTION OF EMBODIMENTS OF THE PRESENT INVENTION

For clarity, the same elements have been designated with the same reference numerals in the various drawings and, further, as usual in the representation of integrated circuits, the various drawings are not to scale.

The principle of the invention is based on an analysis of the physical phenomena which occur during an operation of molecular bonding of two supports comprising materials of different natures. At the propagating front of the bonded area, a local stretching of the supports can be observed. When the Young's modules of the materials of the supports are different, the resulting local deformations are not identical. The bonded surface of the support having the lowest Young's modulus stretches more than the bonded surface of the support having the highest Young's modulus. The bonding then occurs while the supports are deformed. After having bonded the two supports and removed one of the supports to only leave a thin layer bonded to the other support, deformations can be observed in the thin layer.

Generally, on bonding of an integrated circuit wafer on a final glass support, the integrated circuit wafer rests on an initial support, which is removed afterwards, and which is a single-crystal silicon substrate. The inventors have shown that, during the molecular bonding of the integrated circuit wafer on the final support, the resulting deformations observed in the integrated circuit wafer are essentially due to the nature of the initial support material used for the application of the integrated circuit wafer against the final support. Indeed, the thickness of the integrated circuit wafer is low as compared with the thickness of the initial support, and it may be neglected. The Young's modulus of glass is smaller than the Young's modulus of silicon so that, after the bonding, a negative enlargement can be observed in a plane of the integrated circuit wafer parallel to the bonded surfaces.

The inventors have shown that the relative deformation differences in the integrated circuit wafer originate from the anisotropic mechanical properties of the material forming the initial support. In particular, the inventors have shown that the relative deformation differences in the integrated circuit wafer are due to variations of the Young's modulus of the material forming the initial support along the direction considered in a plane parallel to the bonded surfaces.

FIG. 2 shows a curve C0 of the variation of the Young's modulus in a (100) crystallographic plane of single-crystal silicon support 12. The Young's modulus varies between a value of approximately 130 GPa for crystallographic directions [100] and [010] and a value of 170 GPa for crystallographic direction[110].

For SOI structures currently available for sale, surface 13 of silicon initial support 12 generally corresponds to a (100) crystallographic surface. The inventors have observed that the relative narrowing is in the order of 16 ppm in crystallographic directions [100] and [010] and is in the order of 24 ppm in crystallographic direction[110].

The principle of the invention is to modify initial support 12 so that the Young's modulus of the initial support is in average substantially uniform independently form the considered direction in a plane perpendicular to the bonded surfaces.

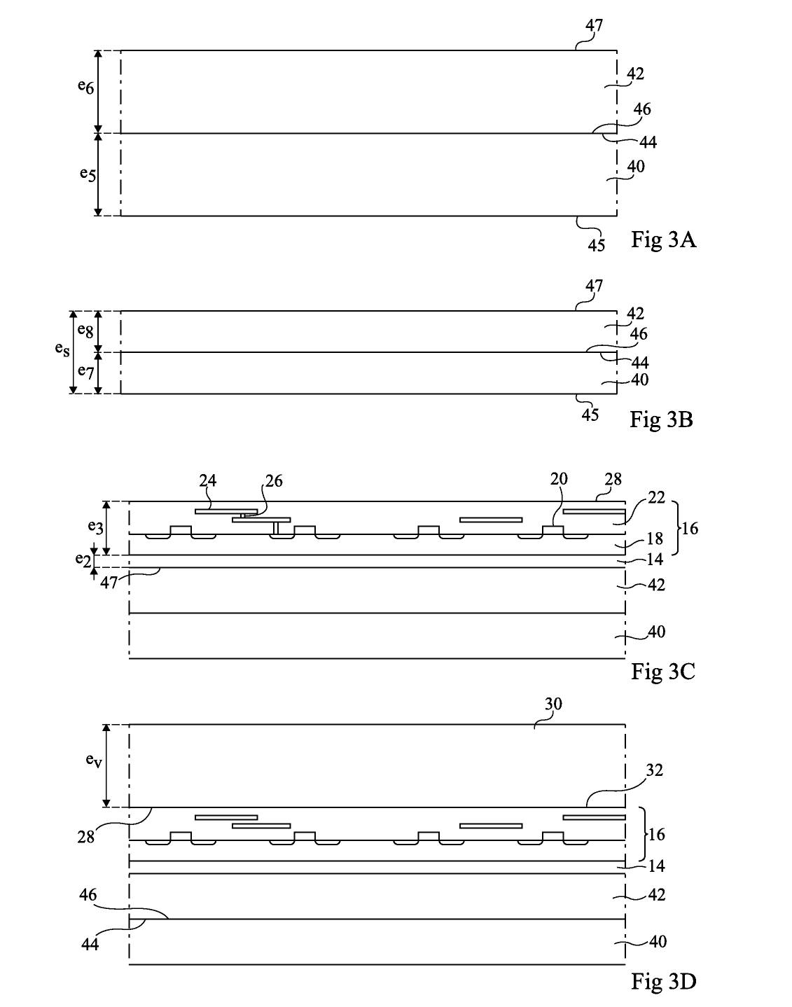

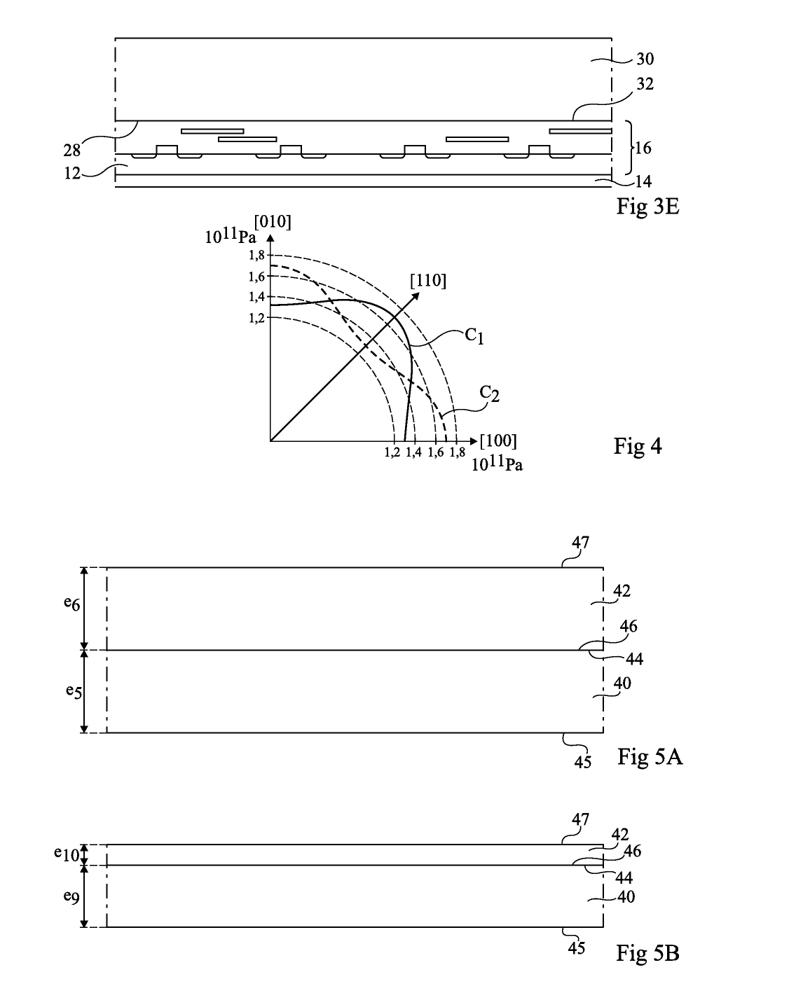

FIGS. 3A to 3E show the structures obtained at successive steps of a first embodiment of a method of manufacturing an integrated circuit wafer on an insulating support according to the invention.

FIG. 3A shows the structure obtained after having bonded two supports 40, 42 to each other. Support 40 is made of single-crystal silicon. Support 40 has a thickness e5 of several hundred micrometers, for example, equal to approximately 700 μm. It for example is a silicon substrate currently available for sale, particularly for the manufacturing of integrated circuits. Support 40 comprises two parallel surfaces 44 and 45 which each correspond to a (100) crystallographic surface. Support 42 is made of single-crystal silicon. Support 42 has a thickness e6 of several hundred micrometers, for example, equal to approximately 700 μm. It for example is a silicon substrate currently available for sale, particularly for the manufacturing of integrated circuits. Support 42 comprises two parallel surfaces 46 and 47 which each correspond to a (100) crystallographic surface. Thicknesses e5 and e6 are equal. Surface 44 of support 40 is bonded to surface 46 of support 42. The bonding between supports 40 and 42 may be performed in any manner. It for example is a molecular bonding.

Support 40 is oriented with respect to support 42 so that in a plane parallel to surfaces 44 and 46, crystallographic direction [100] of support 40 has a 45° orientation with respect to crystallographic direction [100] of support 42.

FIG. 3B shows the structure obtained after a step of thinning each initial support 40 and 42. This step may be carried out by a method of chem.-mech. polishing of each initial support 40 and 42. Thickness e5 of initial support 40 is decreased to a thickness e7 which may be in the order of 350 μm. Thickness e6 of initial support 42 is decreased to a thickness e8 which may be in the order of 350 μm. Thicknesses e7 and e8 are equal. Advantageously, the sum of thicknesses e7 and e8 is equal to approximately 700 μm to correspond to the standard thickness of silicon substrates conventionally used in integrated circuit manufacturing methods.

FIG. 3C shows the structure obtained after conventional steps of manufacturing an SOI-type structure where the support of the SOI structure corresponds to a stack of initial supports 40 and 42. In particular, insulating layer 14 has been formed on support 42. Insulating layer 14 is covered with integrated circuit wafer 16.

FIG. 3D shows the structure obtained after molecular bonding between surface 28 of integrated circuit wafer 16 and surface 32 of final support 30. Final support 30 is made of an insulating and transparent material. It for example is glass. It for example is borosilicate glass commercialized by Corning under trade name Eagle 2000.

In known fashion, the molecular bonding method may comprise steps of preparing surfaces 28 and 32 to be bonded. A treatment may be carried out so that the roughness of surfaces 28 and 32 is adapted to the performing of a molecular bonding. The preparation steps may further comprise the cleaning of surfaces 28 and 32 aiming at removing most of the particles present on surfaces 28 and 32 having a diameter, for example, greater than 0.2 μm. The preparation steps may further comprise a chemical treatment of surfaces 28 and 32 to promote a molecular bonding of hydrophilic or hydrophobic type.

The bonding may be performed at ambient temperature. The bonding may be initiated by placing surfaces 28 and 32 against each other and by applying a local pressure on one of the supports. The bonding then starts in an initiation area and a bonding propagating front spreads from the initiation area until surface 28 is totally bonded to surface 32. When supports 30, 40, and 42 are cylindrical, the initiation area may be provided in the central region of surfaces 28 and 32. As a variation, the initiation area may be located on one side of surfaces 28 and 32. An anneal step may then be carried out at a temperature lower than the maximum temperature authorized for the materials used. When final support 30 is made of glass, the anneal may be performed up to a temperature from 400° C. to 500° C. for a duration of at least 1 hour, and generally of a plurality of hours, to increase the bonding energy.

FIG. 3E shows the structure obtained after the removal of initial supports 40 and 42. The removal of initial supports 40 and 42 may comprise a chem.-mech. polishing step to remove most of supports 40, 42 followed by a selective chemical etching to remove the rest of initial support 42. Insulating layer 14 may be used as a stop layer on removal of initial supports 40 and 42.

The method generally carries on with the forming of conductive vias through insulating layer 14 and silicon layer 12.

FIG. 4 schematically shows variation curves of the Young's modulus in a plane parallel to surfaces 44 and 46 respectively for support 40 (curve in full lines C1) and for support 42 (curve C2 in dotted lines). The crystallographic directions of surface 44 being inclined by 45° with respect to the crystallographic directions of surface 46, the maximum values of curve C1 approximately correspond to the minimum values of curve C2. Thereby, the average Young's modulus of the structure formed of the two supports 40 and 42 is substantially constant independently from the considered direction in a plane perpendicular to surfaces 44 and 46.

According to a second embodiment of the invention, the thicknesses of initial supports 40 and 42 are selected so that integrated circuit wafer 16 comprises substantially no deformations after the bonding step. This may be advantageous since even if uniform deformations in integrated circuit wafer 16 may be generally at least partly compensated for by the exposure device, this results in additional adjustment steps which are not compatible with the carrying out of a manufacturing process at an industrial scale.

During the phase of bonding between the final support and the initial support, the elastic energies stored in each support are equal, which translates as relation (1) hereafter:

$$\frac{1}{2} {V}_{v} {E}_{v} {ɛ}_{v} = \frac{1}{2} {V}_{s} {E}_{s} {ɛ}_{s} \qquad ( 1 )$$

where Vv is the volume of the final support, Vs is the volume of the initial support, Ev is the Young's modulus of the final support, Es is the Young's modulus of the initial support, εv is the deformation of the final support, and εs is the deformation of the initial support. Young's modules Ev and Es are the Young's modules measured in a plane parallel to the bonded surfaces. Young's modules Es or Ev of relation (1) may correspond to average values.

The inventors have shown that when deformations εv and εs are equal, this means that, after bonding, the initial support and the final support find a state of equilibrium with no deformation. It is possible to impose for deformation εv in the final support to be equal to deformation εs in the initial support if volumes Vv and Vs verify relation (2) hereafter:

VᵥEᵥ=VₛEₛ (2)

The initial and final supports having the same opposite-facing surface area, relation (2) becomes relation (3) hereafter:

$${e}_{s} = \frac{{E}_{v}}{{E}_{s}} {e}_{v} \qquad ( 3 )$$

where es is the thickness of the initial substrate and ev is the thickness of the final substrate. Generally, for the forming of an integrated circuit wafer on a glass support, the Young's modulus of the glass support is approximately 70 GPa while the Young's modulus of the initial single-crystal silicon support is approximately 140 GPa. Thickness es of the initial support is then obtained by relation (4) hereafter:

eₛ≈0.5eᵥ (4)

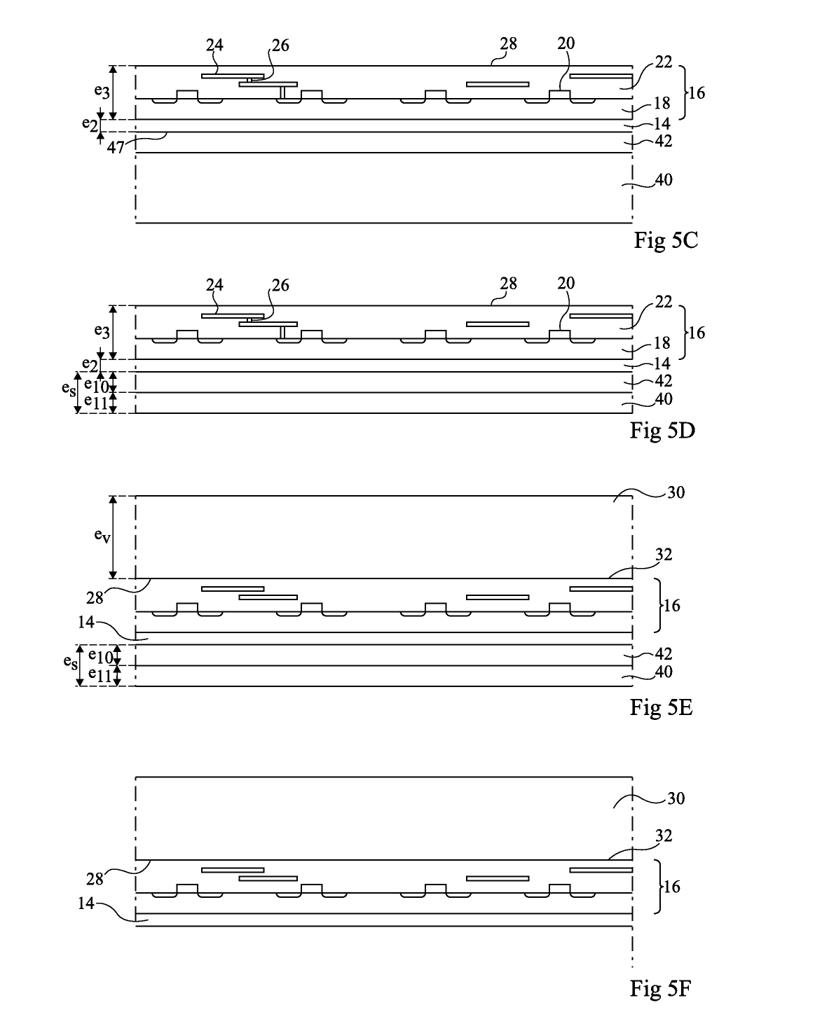

FIGS. 5A to 5E show the structures obtained at successive steps of the second embodiment of a method of manufacturing an integrated circuit wafer on an insulating support according to the invention.

FIG. 5A shows a structure identical to the structure shown in FIG. 3A. In particular, support 40 is oriented with respect to support 42 so that in a plane parallel to surfaces 44 and 46, crystallographic direction [100] of support 40 has a 45° orientation with respect to crystallographic direction [100] of support 42.

FIG. 5B shows the structure obtained after a step of thinning each initial support 40 and 42. This step may be carried out by a method of chem.-mech. polishing of each initial support 40 and 42. Thickness e5 of initial support 40 is decreased to a thickness e9 which may be in the order of 525 μm. Thickness e6 of initial support 42 is decreased to a thickness e10 which may be in the order of 175 μm. Thicknesses e9 and e10 are not equal. Advantageously, the sum of thicknesses e9 and e10 is equal to approximately 700 μm to correspond to the standard thickness of silicon substrates conventionally used in integrated circuit manufacturing methods.

FIG. 5C shows the structure obtained after conventional steps of manufacturing of an SOI-type structure where the support of the SOI structure corresponds to the stack of initial supports 40 and 42. In particular, insulating layer 14 has been formed on support 42. Insulating layer 14 is covered with integrated circuit wafer 16.

FIG. 5D shows the structure obtained after a step of thinning initial support 40. This step may be carried out by a method of chem.-mech. polishing of initial support 40. Thickness e9 of initial support 40 is decreased to a thickness e11 which may be in the order of 175 μm. Thicknesses e10 and e11 are equal.

FIG. 5E shows the structure obtained after the performing of a molecular bonding between surface 20 of integrated circuit wafer 16 and surface 32 of final support 30, as previously described in relation with FIG. 3D.

FIG. 5F corresponds to the structure obtained after the removal of initial supports 40 and 42 as previously described in relation with FIG. 3E. The relative deformations in integrated circuit wafer 16 which result from the bonding operation are then smaller than 5 ppm.

According to a third embodiment, the material forming initial support 12 is selected so that, in a plane parallel to bonding surface 28, the Young's modulus of initial support 12 is isotropic. For this purpose, initial single-crystal silicon support 12 is selected so that the surface of initial support 12 covered with insulating layer 14 corresponds to a crystallographic surface [111]. Indeed, the inventors have shown that, surprisingly, the crystallographic nature of the materials forming integrated circuit wafer 16 has no influence in the appearing of deformations in integrated circuit wafer 16 during the bonding operation. Only the crystallographic nature of initial support 12 matters. In conventional integrated circuit manufacturing processes, the silicon supports used are supports having as external surfaces crystallographic surfaces of type (100) since this type of silicon support has the lowest manufacturing costs. The third embodiment is based on the observed fact that the use of a single-crystal silicon support different from conventionally-used single-crystal silicon supports enables to decrease, or even to suppress, deformation differences in the integrated circuit wafer.

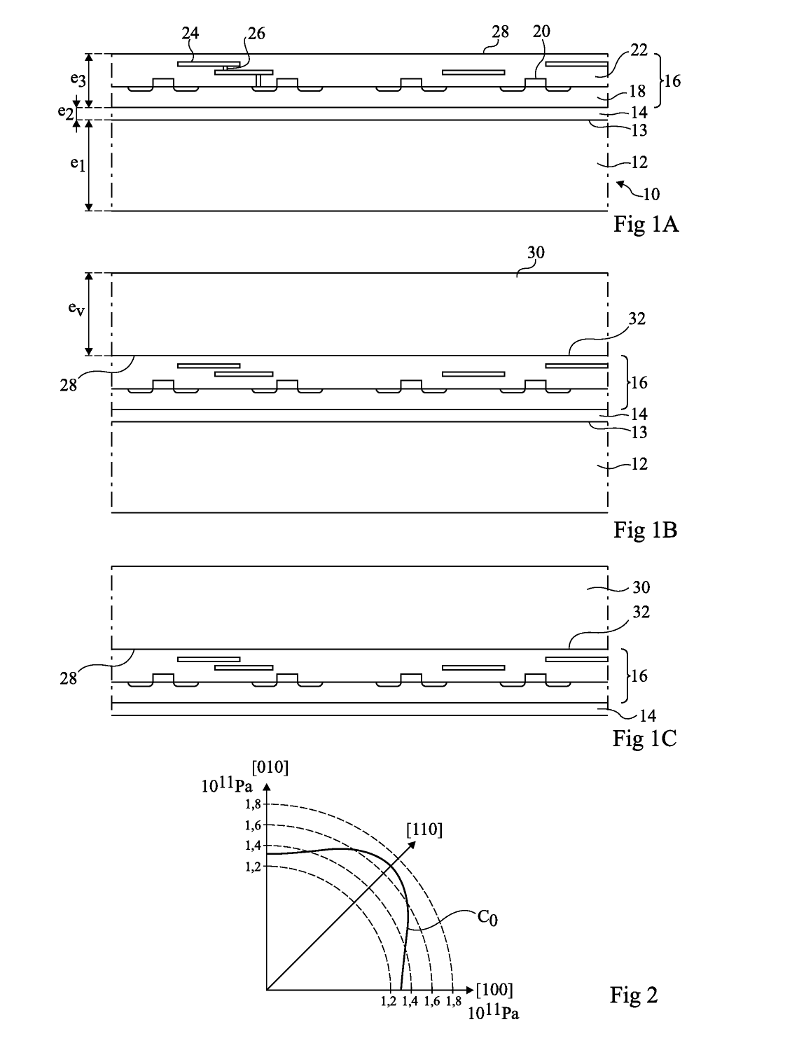

The third embodiment of the method of manufacturing an integrated circuit wafer on an insulating support may comprise the same steps as those previously described in relation with FIGS. 1A to 1C, the only difference being that the surface of initial support 12 covered with insulating layer 14 corresponds to a [111] crystallographic surface.

According to a variation of the third embodiment, thickness es of support 12 may further verify above relation (3). Integrated circuit wafer 16 then substantially comprises no deformation after the bonding step.

Specific embodiments of the present invention have been described. Various alterations and modifications will occur to those skilled in the art. In particular, although in the previously-described embodiment, the final support is made of glass and the initial support is made of silicon, it should be clear that the present invention may apply to the molecular bonding of any type of material having different Young's modules. As an example, the initial support and/or the final support may be made of a semiconductor material, for example, silicon, germanium, or gallium arsenide, of an isolating material, for example, quartz or sapphire, or of any other low-cost material capable of being used to form a handle substrate, for example, a polymer.

1. A method of manufacturing a multilayer structure on a first support made of a first material having a Young's modulus Ev, the method comprising the successive steps of:
providing a second support having a planar surface covered with the multilayer structure, the second support being made of a second material having a Young's modulus Es, different from Young's modulus Ev, and a thickness es, the average of Young's modulus Es across thickness es, measured along any direction in a plane parallel to said surface, being constant to within 10%;
bonding the first support to the multilayer structure; and
removing the second support.

2. The manufacturing method of claim 1, wherein the second material is a single-crystal material.

3. The manufacturing method of claim 1, wherein the second support comprises a stack of a third support having a first planar surface and of a fourth support having a second planar surface in contact with the first surface, the first and second surfaces being parallel to said surface, the first and second surfaces being crystallographic surfaces of type (001) and wherein the [100] crystallographic direction of the first surface is inclined by 45° with respect to the [100] crystallographic direction of the second surface.

4. The manufacturing method of claim 1, wherein the first support has a thickness ev and wherein thickness es verifies, to within 10%, relation:
$${e}_{s} = \frac{{E}_{v}}{{E}_{s}} {e}_{v} .$$

5. The manufacturing method of claim 4, wherein the second support initially has a thickness greater than thickness es, the method further comprising thinning the second support down to thickness es.

6. The manufacturing method of claim 1, wherein the second material is single-crystal silicon.

7. The manufacturing method of claim 6, wherein the surface is a [111] crystallographic surface.

8. The manufacturing method of claim 1, wherein the first material is glass.

9. A support for a multilayer structure, the multilayer structure being intended to be bonded to an additional support made of a first material having a Young's modulus Ev, the support having a planar surface covered with the multilayer structure, the support being made of a second material having a Young's modulus Es, different from Young's modulus Ev, and a thickness es, the average of Young's modulus Es across thickness es, measured along any direction in a plane parallel to said surface, being constant to within 10%.

10. The support of claim 9, wherein the second material is a single-crystal material.

11. The support of claim 10, comprising a stack of a third support having a first planar surface and of a fourth support having a second planar surface in contact with the first surface, the first and second surfaces being parallel to said surface, the first and second surfaces being crystallographic surfaces of type (001) wherein the [100] crystallographic direction of the first surface is inclined by 45° with respect to the [100] crystallographic direction of the second surface.

12. The support of claim 10, wherein the second material is single-crystal silicon, said surface being a [111] crystallographic surface.

13. The support of claim 9, wherein the additional support has a thickness ev and wherein thickness es verifies, to within 10%, relation:
$${e}_{s} = \frac{{E}_{v}}{{E}_{s}} {e}_{v} .$$

14. The manufacturing method of claim 2, wherein the second support comprises a stack of a third support having a first planar surface and of a fourth support having a second planar surface in contact with the first surface, the first and second surfaces being parallel to said surface, the first and second surfaces being crystallographic surfaces of type and wherein the [100] crystallographic direction of the first surface is inclined by 45° with respect to the [100] crystallographic direction of the second surface.

15. The manufacturing method of claim 1, wherein the first support has a thickness ev and wherein thickness es verifies, to within 10%, relation:
$${e}_{s} = \frac{{E}_{v}}{{E}_{s}} {e}_{v} .$$

16. The support of claim 9, comprising a stack of a third support having a first planar surface and of a fourth support having a second planar surface in contact with the first surface, the first and second surfaces being parallel to said surface, the first and second surfaces being crystallographic surfaces of type (001) wherein the [100] crystallographic direction of the first surface is inclined by 45° with respect to the [100] crystallographic direction of the second surface.

17. The support of claim 9, wherein the second material is single-crystal silicon, said surface being a [111] crystallographic surface.

18. The support of claim 10, wherein the additional support has a thickness ev and wherein thickness es verifies, to within 10%, relation:
$${e}_{s} = \frac{{E}_{v}}{{E}_{s}} {e}_{v} .$$

19. The support of claim 11, wherein the additional support has a thickness ev and wherein thickness es verifies, to within 10%, relation:
$${e}_{s} = \frac{{E}_{v}}{{E}_{s}} {e}_{v} .$$

20. The support of claim 12, wherein the additional support has a thickness ev and wherein thickness es verifies, to within 10%, relation:
$${e}_{s} = \frac{{E}_{v}}{{E}_{s}} {e}_{v} .$$
